(19) United States
(12) Patent Application Publication
(10) Pub. No.: US 2006/0130757 A1
(43) Pub. Date: Jun. 22, 2006

(54) Apparatus for active dispersion of precursors

(76) Inventor: YiCheng Li, Schenectady, NY (US)

Correspondence Address: DLA PIPER RUDNICK GRAY CARY US LLP, P. O. BOX 9271, RESTON, VA, 20195, US

(21) Appl. No.: 11/017,643

(22) Filed: Dec. 22, 2004

(51) Int. Cl. C23C 16/00

(52) U.S. Cl. 118/715

(57) ABSTRACT

An apparatus for controlling precursor chemistry. The apparatus includes a chamber including a mixing space, at least one input coupled to the mixing space; and at least one output coupled to the mixing space. A motor subassembly coupled to the chamber and coupled to a mixing element in the mixing space. A controller coupled to the motor subassembly and to the chamber.

### FIELD OF THE INVENTION

The invention relates to using a precursor in a deposition system to deposit thin-films, and more particularly to an apparatus for the active dispersion of the precursor.

### BACKGROUND OF THE INVENTION

Integrated circuit and device fabrication requires deposition of electronic materials on substrates. Material deposition is often accomplished by plasma-enhanced chemical vapor deposition (PECVD), wherein a substrate (wafer) is placed in a reaction chamber and exposed to an ambient of reactive gases. The gases react on the wafer surface to form a film. The deposited film may be a permanent part of the substrate or finished circuit. In this case, the film characteristics are chosen to provide the electrical, physical, or chemical properties required for circuit operation. In other cases, the film may be employed as a temporary layer that enables or simplifies device or circuit fabrication.

During the deposition process, one or more processing steps can be performed and can affect the quality of the deposited film. One potential problem is precursor chemistry.

### SUMMARY OF THE INVENTION

An apparatus for controlling precursor chemistry includes a chamber including a mixing space, at least one input coupled to the mixing space, and at least one output coupled to the mixing space; a motor subassembly coupled to the chamber and coupled to a mixing element in the mixing space; and a controller coupled to the motor subassembly and to the chamber.

### BRIEF DESCRIPTION OF THE DRAWINGS

In the drawings:

FIG. 1 illustrates a simplified block diagram for a deposition system in accordance with an embodiment of the invention;

FIG. 2 illustrates a deposition system for depositing a metal film on a substrate from a metal-carbonyl precursor according to another embodiment of the invention; and

FIG. 3 shows a simplified block diagram of an active dispersion device in accordance with an embodiment of the invention.

### DETAILED DESCRIPTION OF SEVERAL EMBODIMENTS

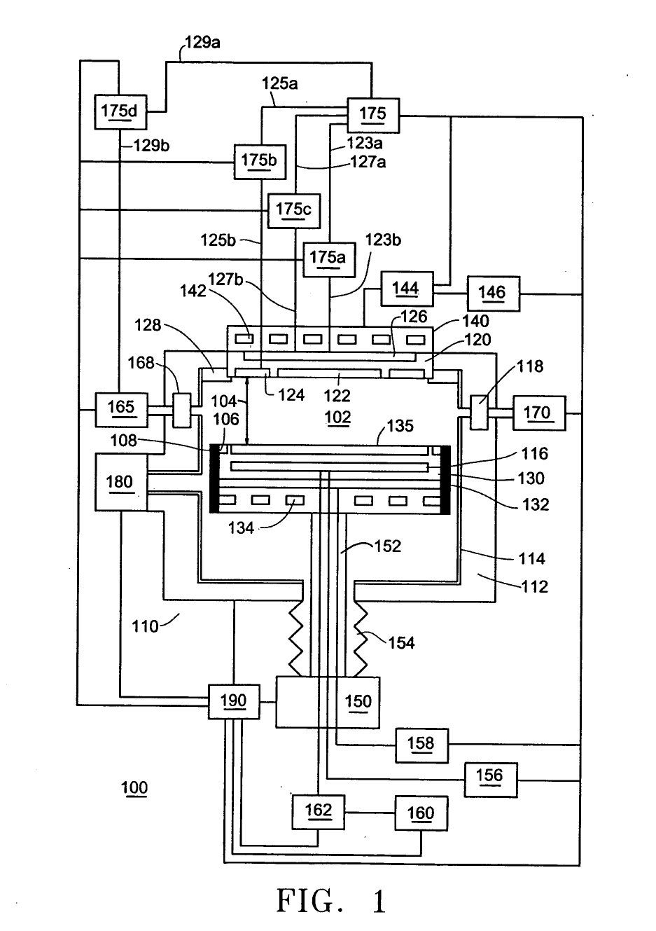

FIG. 1 illustrates a simplified block diagram for a deposition system in accordance with an embodiment of the invention. In the illustrated embodiment, PECVD system 100 comprises processing chamber 110, upper electrode 140 as part of a capacitively coupled plasma source, showerhead assembly 120, substrate holder 130 for supporting substrate 135, pressure control system 180, and controller 190.

In one embodiment, PECVD system 100 can comprise a remote plasma system 165 that can be coupled to the processing chamber 110 using a valve 168. In another embodiment, a remote plasma system and valve are not required. The remote plasma system 165 can be used for chamber cleaning.

In one embodiment, PECVD system 100 can comprise a pressure control system 180 that can be coupled to the processing chamber 110. For example, the pressure control system 180 can comprise a throttle valve (not shown) and a turbomolecular pump (TMP) (not shown) and can provide a controlled pressure in processing chamber 110. In alternate embodiments, the pressure control system can comprise a dry pump. For example, the chamber pressure can range from approximately 0.1 mTorr to approximately 100 Torr. Alternatively, the chamber pressure can range from approximately 0.1 Torr to approximately 20 Torr.

Processing chamber 110 can facilitate the formation of plasma in process space 102. PECVD system 100 can be configured to process substrates of any size, such as 200 mm substrates, 300 mm substrates, or larger substrates. Alternately, the PECVD system 100 can operate by generating plasma in one or more processing chambers.

PECVD system 100 comprises a showerhead assembly 120 coupled to the processing chamber 110. Showerhead assembly is mounted opposite the substrate holder 130. Showerhead assembly 120 comprises a center region 122, an edge region 124, and a sub region 126. Shield ring 128 can be used to couple showerhead assembly 120 to processing chamber 110.

Gas supply system 175 can be coupled to a first active dispersion device 175a using a process gas line 123a, or alternately the first active dispersion device 175a and/or the process gas line 123a may not be required. Gas supply system 175 can be coupled to a second active dispersion device 175b using a process gas line 125a, or alternately the second active dispersion device 175b and/or the process gas line 125a may not be required. Gas supply system 175 can be coupled to a third active dispersion device 175c using a proess gas line 127a, or alternately the third active dispersion device 175c and/or the process gas line 127a may not be required. Gas supply system 175 can be coupled to a fourth active dispersion device 175d using a process gas line 129a, or alternately the fourth active dispersion device 175d and/or the process gas line 129a may not be required.

Center region 122 can be coupled to the first active dispersion device 175a by a process gas line 123b, or alternately process gas line 123b may not be used. In other embodiments, the center region 122 may be coupled directly to the gas supply system 175, or may not be coupled to the gas supply system 175. Edge region 124 can be coupled to the second active dispersion device 175b by a process gas line 125b, or alternately process gas line 125b may not be used. In other embodiments, the edge region 124 may be coupled directly to the gas supply system 175, or may not be coupled to the gas supply system 175. Sub region 126 can be coupled to the third active dispersion device 175c by a process gas line 127b, or alternately process gas line 127b may not be used. In other embodiments, the sub region 126 may be coupled directly to the gas supply system 175, or may not be coupled to the gas supply system 175.

Remote plasma system 165 can be coupled to a fourth active dispersion device 175d by a process gas line 129b, or alternately process gas line 129b may not be used. In other embodiments, the remote plasma system 165 may be coupled directly to the gas supply system 175, or may not be coupled to the gas supply system 175. In other embodiments, additional gas lines (not shown) may be provided for separating a precursor supply line from a process gas supply line.

Controller 190 can be coupled to the first active dispersion device 175a, the second active dispersion device 175b, the third active dispersion device 175c, and the fourth active dispersion device 175d, and can be used to control the operation of these devices. Gas supply system 175 provides a first process gas to the center region 122, a second process gas to the edge region 124, and a third process gas to the sub region 126. The gas chemistries and flow rates can be individually controlled to these regions. Alternately, the center region and the edge region can be coupled together as a single primary region, and the gas supply system can provide the first process gas and/or the second process gas to the primary region. In alternate embodiments, any of the regions can be coupled together and the gas supply system can provide one or more process gasses as appropriate.

In addition, a fourth process gas can be provided to the remote plasma system 165. The gas chemistries and flow rates can be individually controlled to the remote plasma system 165.

The gas supply system 175 can comprise at least one vaporizer (not shown) for providing precursors. Alternately, a vaporizer is not required. In an alternate embodiment, a bubbling system can be used.

PECVD system 100 comprises an upper electrode 140 that can be coupled to showerhead assembly 120 and coupled to the processing chamber 110. Upper electrode 140 can comprise temperature control elements 142. Upper electrode 140 can be coupled to a first RF source 146 using a first match network 144. Alternately, a separate match network is not required.

The first RF source 146 provides a TRF signal to the upper electrode, and the first RF source 146 can operate in a frequency range from approximately 0.1 MHz. to approximately 200 MHz. The TRF signal can be in the frequency range from approximately 1 MHz. to approximately 100 MHz, or alternatively in the frequency range from approximately 2 MHz. to approximately 60 MHz. The first RF source can operate in a power range from approximately 0 watts to approximately 10000 watts, or alternatively the first RF source operates in a power range from approximately 0 watts to approximately 5000 watts.

Upper electrode 140 and RF source 146 are parts of a capacitively coupled plasma source. The capacitively couple plasma source may be replaced with or augmented by other types of plasma sources, such as an inductively coupled plasma (ICP) source, a transformer-coupled plasma (TCP) source, a microwave powered plasma source, an electron cyclotron resonance (ECR) plasma source, a Helicon wave plasma source, and/or a surface wave plasma source. As is well known in the art, upper electrode 140 may be eliminated or reconfigured in the various suitable plasma sources.

Substrate 135 can be transferred into and out of processing chamber 110 through a slot valve (not shown) and chamber feed-through (not shown) via robotic substrate transfer system (not shown), and it can be received by substrate holder 130 and mechanically translated by devices coupled thereto. Once substrate 135 is received from substrate transfer system, substrate 135 can be raised and/or lowered using a translation device 150 that can be coupled to substrate holder 130 by a coupling assembly 152.

Substrate 135 can be affixed to the substrate holder 130 via an electrostatic clamping system. For example, an electrostatic clamping system can comprise an electrode 116 and an ESC supply 156. Clamping voltages, which can range from approximately −2000 V to approximately +2000 V, for example, can be provided to the clamping electrode. Alternatively, the clamping voltage can range from approximately −1000 V to approximately +1000 V. In alternate embodiments, an ESC system and supply is not required.

Substrate holder 130 can comprise lift pins (not shown) for lowering and/or raising a substrate to and/or from the surface of the substrate holder. In alternate embodiments, different lifting means can be provided in substrate holder 130. In alternate embodiments, gas can be delivered to the backside of substrate 135 via a backside gas system to improve the gas-gap thermal conductance between substrate 135 and substrate holder 130.

A temperature control system can also be provided. Such a system can be utilized when temperature control of the substrate is required at elevated or reduced temperatures. For example, a heating element 132, such as resistive heating elements, or thermo-electric heaters/coolers can be included, and substrate holder 130 can further include a heat exchange system 134. Heating element 132 can be coupled to heater supply 158. Heat exchange system 134 can include a re-circulating coolant flow means that receives heat from substrate holder 130 and transfers heat to a heat exchanger system (not shown), or when heating, transfers heat from the heat exchanger system.

Also, electrode 116 can be coupled to a second RF source 160 using a second match network 162. Alternately, a match network is not required.

The second RF source 160 provides a bottom RF signal (BRF) to the lower electrode 116, and the second RF source 160 can operate in a frequency range from approximately 0.1 MHz. to approximately 200 MHz. The BRF signal can be in the frequency range from approximately 0.2 MHz. to approximately 30 MHz, or alternatively, in the frequency range from approximately 0.3 MHz. to approximately 15 MHz. The second RF source can operate in a power range from approximately 0.0 watts to approximately 1000 watts, or alternatively, the second RF source can operate in a power range from approximately 0.0 watts to approximately 500 watts. In various embodiments, the lower electrode 116 may not be used, or may be the sole source of plasma within the chamber, or may augment any additional plasma source.

PECVD system 100 can further comprise a translation device 150 that can be coupled by a bellows 154 to the processing chamber 110. Also, coupling assembly 152 can couple translation device 150 to the substrate holder 130. Bellows 154 is configured to seal the vertical translation device from the atmosphere outside the processing chamber 110.

Translation device 150 allows a variable gap 104 to be established between the showerhead assembly 120 and the substrate 135. The gap can range from approximately 1 mm to approximately 200 mm, and alternatively, the gap can range from approximately 2 mm to approximately 80 mm. The gap can remain fixed or the gap can be changed during a deposition process.

Additionally, substrate holder 130 can further comprise a focus ring 106 and ceramic cover 108. Alternately, a focus ring 106 and/or ceramic cover 108 are not required.

At least one chamber wall 112 can comprise a coating 114 to protect the wall. For example, the coating 114 can comprise a ceramic material. In an alternate embodiment, a coating is not required. Furthermore, a ceramic shield (not shown) can be used within processing chamber 110. In addition, a temperature control system can be used to control the chamber wall temperature. For example, ports can be provided in the chamber wall for controlling temperature. Chamber wall temperature can be maintained relatively constant while a process is being performed in the chamber.

Also, the temperature control system can be used to control the temperature of the upper electrode. Temperature control elements 142 can be used to control the upper electrode temperature. Upper electrode temperature can be maintained relatively constant while a process is being performed in the chamber.

Furthermore, PECVD system 100 can also comprise a purging system 195 that can be used for controlling contamination. Alternately, a purging system may not be required.

In an alternate embodiment, processing chamber 110 can further comprise a monitoring port (not shown). A monitoring port can, for example, permit optical monitoring of process space 102.

PECVD system 100 also comprises a controller 190. Controller 190 can be coupled to chamber 110, showerhead assembly 120, substrate holder 130, gas supply system 170, upper electrode 140, first RF match 144, first RF source 146, translation device 150, ESC supply 156, heater supply 158, second RF match 162, second RF source 160, purging system 195, remote plasma device 165, and pressure control system 180. The controller can be configured to provide control data to these components and receive data such as process data from these components. For example, controller 190 can comprise a microprocessor, a memory, and a digital I/O port capable of generating control voltages sufficient to communicate and activate inputs to the processing system 100 as well as monitor outputs from the PECVD system 100. Moreover, the controller 190 can exchange information with system components. Also, a program stored in the memory can be utilized to control the aforementioned components of a PECVD system 100 according to a process recipe. In addition, controller 190 can be configured to analyze the process data, to compare the process data with target process data, and to use the comparison to change a process and/or control the deposition tool. Also, the controller can be configured to analyze the process data, to compare the process data with historical process data, and to use the comparison to predict, prevent, and/or declare a fault.

Processing system 100 can be used to deposit one or more low-k dielectric layers, but this is not required for the invention. In alternate embodiments, other materials may be deposited. The substrate holder can be used to establish a gap between an upper electrode surface and a surface of the substrate holder. The gap can range from approximately 1 mm to approximately 200 mm, or alternatively, the gap can range from approximately 2 mm to approximately 80 mm. In alternate embodiments, the gap size can be changed during processing the wafer. During the low-k dielectric deposition process, a TRF signal can be provided to the upper electrode using the first RF source. For example, the first RF source can operate in a frequency range from approximately 0.1 MHz. to approximately 200 MHz. Alternatively, the first RF source can operate in a frequency range from approximately 1 MHz. to approximately 100 MHz, or the first RF source can operate in a frequency range from approximately 2 MHz. to approximately 60 MHz. The first RF source can operate in a power range from approximately 10 watts to approximately 10000 watts, or alternatively, the first RF source can operate in a power range from approximately 10 watts to approximately 5000 watts

Also, during a deposition process, a BRF signal can be provided to the lower electrode in the substrate holder using the second RF source. For example, the second RF source can operate in a frequency range from approximately 0.1 MHz. to approximately 200 MHz. Alternatively, the second RF source can operate in a frequency range from approximately 0.2 MHz. to approximately 30 MHz, or the second RF source can operate in a frequency range from approximately 0.3 MHz. to approximately 15 MHz. The second RF source can operate in a power range from approximately 0.0 watts to approximately 1000 watts, or alternatively, the second RF source can operate in a power range from approximately 0.0 watts to approximately 500 watts. In an alternate embodiment, a BRF signal is not required.

In addition, a showerhead assembly can be provided in the processing chamber and can be coupled to the upper electrode. The showerhead assembly can comprise a center region, an edge region, and a sub region, and the showerhead assembly can be coupled to a gas supply system. A first process gas can be provided to the center region, a second process gas can be provided to the edge region and a third process gas can be provided to the sub region during the deposition process.

Alternately, the center region and the edge region can be coupled together as a single primary region, and gas supply system can provide the first process gas and/or the second process gas to the primary region. In alternate embodiments, any of the regions can be coupled together and the gas supply system can provide one or more process gasses.

The first process gas and the second process gas can comprise a silicon-containing precursor and/or a carbon-containing precursor. An inert gas can also be included. For example, the flow rate for the silicon-containing precursor and the-carbon containing precursor can range from approximately 0.0 sccm to approximately 5000 sccm and the flow rate for the inert gas can range from approximately 0.0 sccm to approximately 10000 sccm. The silicon-containing precursor can comprise monosilane (SiH₄), tetraethylorthosilicate (TEOS), monomethylsilane (1MS), dimethylsilane (2MS), trimethylsilane (3MS), tetramethylsilane (4MS), dimethyldimethoxysilane (DMDMOS), octamethylcyclotetrasiloxane (OMCTS), and/or tetramethylcyclotetrasilane (TMCTS). The carbon-containing precursor can comprise CH₄, C₂H₄, C₂H₂, C₂H₆, C₆H₆ and/or C₆H₅OH. The inert gas can be argon, helium, and/or nitrogen.

In addition, the third process gas can comprise an oxygen containing gas, a fluorine containing gas, and/or an inert gas. For example, the oxygen containing gas can comprise O₂, O₃, CO, NO, N₂O, and/or CO₂; fluorine-containing precursor can comprise CF₄, C₂F₆, C₃F₈, C₄F₈, COF₂, CHF₃, CH₂F₂, CH₃F, SF₆, F₂ and/or NF₃; and the inert gas can comprise N₂, Ar, and/or He. The flow rate for the third process gas can range from approximately 0.0 sccm to approximately 10000 sccm.

The flow rates for the first process gas, the second process gas and third process gas can be independently established during the deposition process.

A pressure control system can be coupled to the chamber, and the chamber pressure can be controlled using the pressure control system. For example, the chamber pressure can range from approximately 0.1 mTorr to approximately 100 Torr.

A temperature control system can be coupled to the substrate holder, and the substrate temperature can be controlled using the temperature control system. For example, the substrate temperature can range from approximately 0° C. to approximately 500° C. The temperature control system can also be coupled to a chamber wall, and the temperature of the chamber wall can be controlled using the temperature control system. For example, the temperature of the chamber wall can range from approximately 0° C. to approximately 500° C. In addition, the temperature control system can be coupled to the showerhead assembly; and the temperature of the showerhead assembly can be controlled using the temperature control system. For example, the temperature of the showerhead assembly can range from approximately 0° C. to approximately 500° C.

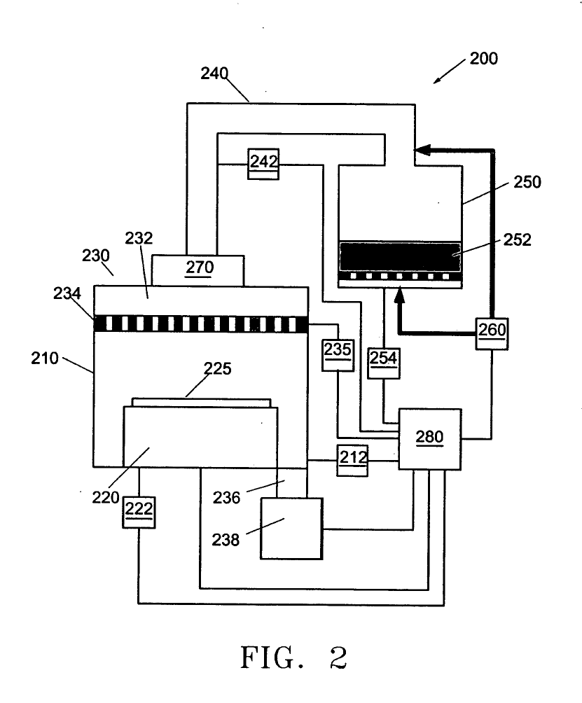

FIG. 2 illustrates a deposition system 200 for depositing a metal film on a substrate from a metal-carbonyl precursor according to another embodiment of the invention. The deposition system 200 comprises a process chamber 210 having a substrate holder 220 configured to support a substrate 225, upon which the metal film can be formed. The process chamber 210 is coupled to a metal precursor evaporation system 250 via a vapor precursor delivery system 240 and active dispersion device 270.

The process chamber 210 is further coupled to a vacuum pumping system 238 through a duct 236. The pumping system 238 is configured to evacuate the process chamber 210, active dispersion device 270, vapor precursor delivery system 240, and metal precursor evaporation system 250 to a pressure suitable for forming the metal film on substrate 225, and suitable for evaporation of the metal precursor 252 in the metal precursor evaporation system 250.

Referring still to FIG. 2, the metal precursor evaporation system 250 is configured to store a metal precursor 252, and heat the metal precursor 252 to a temperature sufficient for evaporating the metal precursor 252, while introducing vapor phase metal precursor to the vapor precursor delivery system 240 and the active dispersion device 270. The metal precursor 252 can comprise a solid metal precursor. Additionally, the metal precursor can include a metal-carbonyl. For instance, the metal-carbonyl precursor can have the general formula Mₓ(CO)_{y}, and can comprise a tungsten-carbonyl, a molybdenum carbonyl, a cobalt carbonyl, a rhodium carbonyl, a rhenium carbonyl, a chromium carbonyl, or an osmium carbonyl precursor, or a combination of two thereof. These metal-carbonyls include, but are not limited to, W(CO)₆, Ni(CO)₄, Mo(CO)₆, Co₂(CO)₈, Rh₄(CO)₁₂, Re₂(CO)₁₀, Cr(CO)₆, Ru₃(CO)₁₂, or Os₃(CO)₁₂, or a combination of two or more thereof.

In order to achieve the desired temperature for evaporating the metal precursor 252 (or subliming the solid metal precursor 252), the metal precursor evaporation system 250 is coupled to an evaporation temperature control system 254 configured to control the evaporation temperature. For instance, the temperature of the metal precursor 252 is generally elevated to approximately 40 to 45° C. in conventional systems in order to sublime ruthenium carbonyl Ru₃(CO)₁₂. At this temperature, the vapor pressure of the Ru₃(CO)₁₂ ranges from approximately 1 to approximately 3 mTorr. As the metal precursor is heated to cause evaporation (or sublimation), a carrier gas can be passed over the metal precursor, beneath the metal precursor, or through the metal precursor, or any combination thereof. The carrier gas can include, for example, an inert gas, such as a noble gas, He, Ne, Ar, Kr, or Xe, or a combination of two or more thereof. Alternately, other embodiments contemplate omitting a carrier gas.

According to an embodiment of the invention, a precursor gas can be added to the carrier gas. According to another embodiment of the invention, the precursor gas can replace the carrier gas. For example, a gas supply system 260 can be coupled to the metal precursor evaporation system 250, and it can be configured to supply a carrier gas, a precursor gas, or a mixture thereof, beneath the metal precursor 252, or above the metal precursor 252. In addition, the gas supply system 260 is coupled to the vapor precursor delivery system 240 downstream from the metal precursor evaporation system 250 that can supply the carrier gas, the precursor stabilization gas, or both, to the vapor precursor delivery system 240 and the active dispersion device 270. The gas supply system 260 can comprise a carrier gas source, a precursor gas source, one or more control valves, one or more filters, and a mass flow controller. For instance, the flow rate of the carrier gas can be between about 0.1 standard cubic centimeters per minute (sccm) and about 1000 sccm. Alternately, the flow rate of the carrier gas can be between about 10 sccm and about 500 sccm. Still alternately, the flow rate of the carrier gas can be between about 50 sccm and about 200 sccm. According to embodiments of the invention, the flow rate of the precursor gas can range from approximately 0.1 sccm to approximately 1000 sccm. Alternately, the flow rate of the precursor gas can be between about 1 sccm and about 100 sccm.

Downstream from the metal precursor evaporation system 250, the process gas containing the metal precursor gas and the carrier gas flows through the vapor precursor delivery system 240 until it enters an active dispersion device 270 in which the process gas containing the metal precursor gas and the carrier gas are agitated to ensure that a uniform chemical composition is established and/or maintained in the process gas.

Downstream from the vapor precursor delivery system 240, the process gas containing the metal precursor gas and the carrier gas flows through the active dispersion device 270 until it enters a vapor distribution system 230 coupled to the process chamber 210. The vapor precursor delivery system 240 can be coupled to a vapor line temperature control system 242 in order to control the vapor line temperature, and prevent decomposition of the metal precursor vapor as well as condensation of the metal precursor vapor. In an alternate embodiment, the active dispersion device 270 can be coupled to a temperature control system (not shown) in order to control the temperature in the active dispersion device 270, and prevent decomposition of the metal precursor vapor as well as condensation of the metal precursor vapor.

Referring again to FIG. 2, a vapor distribution system 230, coupled to the process chamber 210, comprises a plenum 232 within which the vapor disperses prior to passing through a vapor distribution plate 234 and entering the process chamber 210 above substrate 225. In addition, the vapor distribution plate 234 can be coupled to a distribution plate temperature control system 235 configured to control the temperature of the vapor distribution plate 234.

Once the process gas containing the metal precursor vapor enters the process chamber 210, the metal precursor thermally decomposes upon adsorption at the substrate surface due to the elevated temperature of the substrate 225, and the metal film is formed on the substrate 225. The substrate holder 220 is configured to elevate the temperature of substrate 225, whereby the substrate holder 220 is coupled to a substrate temperature control system 222 configured to control the temperature of substrate 225. For example, the substrate temperature control system 222 can be configured to elevate the temperature of substrate 225 up to approximately 600° C. Additionally, process chamber 210 can be coupled to a chamber temperature control system 212 configured to control the temperature of the chamber walls.

As described above, for example, conventional systems have contemplated operating the metal precursor evaporation system 250, as well as the vapor precursor delivery system 240, within a temperature range of approximately 40 to 45° C. for ruthenium carbonyl in order to prevent metal vapor precursor decomposition, and metal vapor precursor condensation. For example, ruthenium carbonyl precursor can decompose at elevated temperatures to form by-products, such as those illustrated below
Ru₃(CO)₁₂(ad) [symbol] Ru₃(CO)ₓ(ad)+(12−x)CO(g) (1)

or,
Ru₃(CO)ₓ(ad) [symbol] 3Ru(s)+xCO(g) (2)

where these by-products can condense on the interior surfaces of the deposition system. The accumulation of material on these surfaces can cause problems from one substrate to the next, such as process repeatability. Alternatively, for example, ruthenium carbonyl precursor can condense at depressed temperatures to cause recrystallization, viz.
Ru₃(CO)₁₂(g) [symbol] Ru₃(CO)₁₂(ad) (3)

However, within such systems having a small process window, the deposition rate becomes extremely low, due in part to the low vapor pressure of ruthenium carbonyl. Since rhenium carbonyl behaves similarly (i.e., vapor pressure versus temperature), it is expected that one will observe similar results.

Still referring the FIG. 2, the deposition system 200 can further include a control system 280 configured to operate, and control the operation of the deposition system 200. The control system 280 is coupled to the process chamber 210, the substrate holder 220, the substrate temperature control system 222, the chamber temperature control system 212, the vapor distribution system 230, the vapor precursor delivery system 240, the metal precursor evaporation system 250, the gas supply system 260, and the active dispersion device 270.

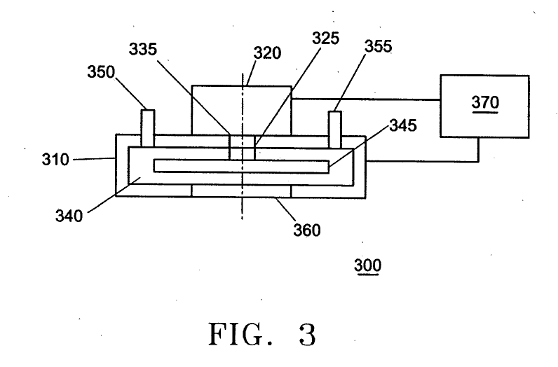

FIG. 3 shows a simplified block diagram of an active dispersion device in accordance with an embodiment of the invention. In the illustrated embodiment, an active dispersion device 300 is shown that includes a chamber 310, a motor subassembly 320 coupled to the chamber 310, a controller 370 coupled to the motor subassembly 320 and coupled to the chamber 310 to monitor conditions in chamber 310. Thus, controller 370 may be coupled to one or more sensors in chamber 310 to measure precursor flow into or out of chamber 310, the speed of mixing element 345, the pressure in chamber 310, and/or any other parameter. In alternate embodiments, the controller 370 may be coupled differently.

In addition, the active dispersion device 300 can comprise a mixing element 345 coupled to a drive shaft 325. The drive shaft 325 is coupled to the motor subassembly 320 through an opening 335 in the chamber wall.

The chamber 310 can also comprise a mixing space 340, at least one process gas input line 350 coupled to the mixing apace 340, at least one precursor gas input line 355 coupled to the mixing apace 340, and at least one outlet 360 coupled to the mixing space 340. In alternate embodiment, the process gas and the precursor may be combined before entering the mixing space 340. In another embodiment, a filter element (not shown) may be included at the chamber output.

In one embodiment, the mixing element 330 can comprise one or more blades that can be rotated to establish and/or maintain a uniform mixture in the mixing space 340, and thereby provide the correct process gas/precursor chemistry to the process chamber. The mixing element 330 can be manufactured using a metal such as stainless steel or aluminum. Alternately, the mixing element can comprise a ceramic material. The mixing element 330 can have a diameter that can range from approximately 200 mm to 300 mm, and the mixing space 340 can have a diameter that can range from 350 mm to 450 mm.

In another alternate embodiment, the active dispersion device 300 may comprise one or more temperature control elements to maintain the proper temperature in the mixing space. For example, the temperature control elements may comprise heating and/or cooling elements (not shown).

Controller 370 can control the rotational speed of the motor assembly and the mixing element 345. The rotational speed can vary from approximately 50 rpm to approximately 50,000 rpm. Alternately, the rotational speed may vary from approximately 70 rpm to approximately 2,400 rpm.

The volume of mixing space 340 can vary from approximately 2 cubic inches to approximately 20 cubic inches. The pressure within the mixing space can vary from approximately 0.1 Torr to approximately 5 Torr.

The flow rate for the carrier gas into the mixing space can vary from approximately 50 sccm to approximately 1,000 sccm. The flow rate for the precursor gas into the mixing space can vary from approximately 50 sccm to approximately 1,000 sccm. The flow rate for the combined carrier gas and precursor gas out of the mixing space can vary from approximately 50 sccm to approximately 1,000 sccm.

The active dispersion device 300 can be used for high molecular weight precursors. For example, the precursors can include: W(CO)₆ with a molecular weight of 351.9; Re₂(CO)₁₀ with a molecular weight of 652.5; Ru₃(CO)₁₂ with a molecular weight of 639.3; and Taimata with a molecular weight of 398.3.

In an alternate embodiment, the active dispersion device 300 may comprise a control valve (not shown) at the output, and the control valve can be opened during one or more steps of a process sequence and closed during other steps of the process sequence. For example, the valve may be closed during mixing step; the mixing time can be determined by the controller; and the mixing time may vary from approximately 2 seconds to approximately 20 seconds.

Although only certain exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

What is claimed is:

1. An apparatus for controlling precursor chemistry, the apparatus comprising:
a chamber including a mixing space, at least one input coupled to the mixing space, and at least one output coupled to the mixing space;
a conduit conducting precursor gas to the at least one inlet;
a motor subassembly coupled to the chamber;
a mixing element in the mixing space coupled to the motor subassembly; and
a controller coupled to the motor subassembly.

2. The apparatus as claimed in claim 1, further comprising:
a processing chamber;
a shower head assembly disposed in the processing chamber; and
means for coupling the at least one output to the showerhead assembly.

3. The apparatus as claimed in claim 2, wherein the processing chamber comprises a chemical vapor deposition (CVD) chamber, a plasma enhanced chemical vapor deposition (PECVD) chamber, or an atomic layer deposition (ALD) chamber, or a combination thereof.

4. The apparatus as claimed in claim 1, wherein the at least one input comprises:
an inert gas input; and
a precursor gas input.

5. The apparatus as claimed in claim 4, wherein the inert gas flows at a rate ranging from approximately 0 sccm to approximately 10000 sccm.

6. The apparatus as claimed in claim 4, wherein the inert gas comprises Ar, He, or N₂, or a combination of two or more thereof.

7. The apparatus as claimed in claim 4, wherein the precursor gas flows at a rate ranging from approximately 0 sccm to approximately 5000 sccm.

8. The apparatus as claimed in claim 4, wherein the precursor gas comprises a silicon-containing precursor, a carbon-containing precursor, a metal-containing precursor, or an inert gas or a combination of two or more thereof.

9. The apparatus as claimed in claim 8, wherein the precursor gas includes the silicon-containing precursor and the silicon-containing precursor comprises monosilane (SiH₄), tetraethylorthosilicate (TEOS), monomethylsilane (1MS), dimethylsilane (2MS), trimethylsilane (3MS), tetramethylsilane (4MS), dimethyldimethoxysilane (DMDMOS), octamethylcyclotetrasiloxane (OMCTS), or tetramethylcyclotetrasilane (TMCTS), or a combination of two or more thereof.

10. The apparatus as claimed in claim 8, wherein the precursor gas includes the carbon-containing precursor and the carbon-containing precursor comprises CH₄, C₂H₄, C₂H₂, C₆H₆, or C₆H₅OH, or a combination of two or more thereof.

11. The apparatus as claimed in claim 8, wherein the precursor gas includes the metal-containing precursor and the metal-containing precursor comprises W(CO)₆, Re₂(CO)₁₀, Ru₃(CO)₁₂, or Taimata, or a combination of two or more thereof.

12. The apparatus as claimed in claim 8, wherein the precursor gas includes the inert gas and the inert gas comprises a noble gas, He, Ne, Ar, Kr, or Xe, or a combination of two or more thereof.

13. The apparatus as claimed in claim 1, wherein the pressure in the mixing chamber is in a range from approximately 0.1 mTorr to approximately 100 Torr.
